(19) United States
(12) Patent Application Publication
(10) Pub. No.: US 2019/0228734 A1
(43) Pub. Date: Jul. 25, 2019

(54) PIXEL STRUCTURE, MANUFACTURING METHOD AND DRIVING METHOD THEREOF, AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Kunkun GAO, Beijing (CN); Rui WANG, Beijing (CN); Dalong MAO, Beijing (CN); Zhonghao HUANG, Beijing (CN); Yongliang ZHAO, Beijing (CN)

(21) Appl. No.: 16/337,254

(22) PCT Filed: May 31, 2018
(86) PCT No.: PCT/CN2018/089179

§ 371 Date: Mar. 27, 2019

(30) Foreign Application Priority Data
Aug. 25, 2017 (CN) 201710745250.1

(51) Int. Cl. G09G 3/36; H01L 27/12; G02F 1/1368; G02F 1/1362; G02F 1/1343

(52) U.S. Cl. CPC G09G 3/3696; H01L 27/1259; H01L 27/124; G02F 1/1368; G02F 1/136286; G02F 1/13439; G09G 2300/0809; G02F 2201/123; G02F 2201/121; G02F 2001/136295; G09G 2320/0247; G09G 2320/0257; G09G 2300/0426; G09G 3/3648

(57) ABSTRACT

The present disclosure provides a pixel structure, a manufacturing method and a driving method thereof, and a display device. The pixel structure includes a plurality of pixel units, each pixel unit includes a first thin film transistor, a pixel electrode, and a common electrode, a drain of the first thin film transistor of the pixel unit is connected to the pixel electrode of the pixel unit. Each one of at least a portion of the plurality of pixel units further includes a second thin film transistor. A drain of the second thin film transistor of the pixel unit is connected to the common electrode of the pixel unit.

### RELATED APPLICATIONS

The present application claims the benefit of Chinese Patent Application No. 201710745250.1, filed on Aug. 25, 2017, the entire disclosures of which are incorporated herein by reference.

### TECHNICAL FIELD

The present disclosure relates to the field of display technology, and particularly to a pixel structure, a manufacturing method and a driving method thereof, and a display device.

### BACKGROUND

Display devices are devices for displaying characters, numbers, symbols, pictures, or images formed including at least two of characters, numbers, symbols, and pictures, providing greater convenience for user's life and work. A typical display device generally includes a display panel. The display panel is provided with a pixel structure including a plurality of pixel units arranged in an array. The screen display of the display device is realized by controlling the pixel units in the pixel structure to display certain gray levels.

### SUMMARY

An embodiment of the present disclosure provides a pixel structure. The pixel structure includes: a plurality of pixel units; each pixel unit includes a first thin film transistor, a pixel electrode, and a common electrode; a drain of the first thin film transistor of the pixel unit is connected to the pixel electrode of the pixel unit; each one of at least a portion of the plurality of pixel units further includes a second thin film transistor; a drain of the second thin film transistor of the pixel unit is connected to the common electrode of the pixel unit.

In some embodiments of the present disclosure, each pixel unit further includes a second thin film transistor, and a drain of the second thin film transistor of the pixel unit is connected to the common electrode of the pixel unit.

In some embodiments of the present disclosure, the plurality of pixel units are arranged in an N×M array; the pixel structure further includes a plurality of gate lines and a plurality of data lines crossing each other to define a plurality of pixel regions; each pixel unit is located in a corresponding pixel region; a quantity of the gate lines is N+1, and a quantity of the data lines is M; for a pixel unit in an i-th row of pixel units, the gate of the first thin film transistor of the pixel unit is connected to an i-th gate line, and the gate of the second thin film transistor of the pixel unit is connected to an (i+1)-th gate line; 1≤i≤N.

In some embodiments of the present disclosure, the plurality of pixel units are arranged in an N×M array; the pixel structure further includes a plurality of gate lines and a plurality of data lines crossing each other to define a plurality of pixel regions; each pixel unit is located in a corresponding pixel region; a quantity of the gate lines is N+1, and a quantity of the data lines is M; for a pixel unit in an i-th row of pixel units, the gate of the second thin film transistor of the pixel unit is connected to an i-th gate line, and the gate of the first thin film transistor of the pixel unit is connected to an (i+1)-th gate line; 1≤i≤N.

In some embodiments of the present disclosure, for a pixel unit in a j-th column of pixel units, a source of the first thin film transistor of the pixel unit is connected to a j-th data line, and a source of the second thin film transistor of the pixel unit is connected to the j-th data line; 1≤j≤M.

An embodiment of the present disclosure further provides a display device including the pixel structure according to any one of the above-mentioned embodiments.

An embodiment of the present disclosure further provides a method for driving the pixel structure according to any one of the above-mentioned embodiments. The method includes: determining a voltage difference between the pixel electrode and the common electrode of each pixel unit based on an image to be displayed; and turning on the first thin film transistor and the second thin film transistor of the pixel unit based on the voltage difference between the pixel electrode and the common electrode of each pixel unit, and charging the pixel electrode and the common electrode respectively.

In some embodiments of the present disclosure, the plurality of pixel units are arranged in an N×M array; the pixel structure further includes a plurality of gate lines and a plurality of data lines crossing each other to define a plurality of pixel regions; each pixel unit is located in a corresponding pixel region; a quantity of the gate lines is N+1, and a quantity of the data lines is M; for a pixel unit in an i-th row of pixel units, the gate of the first thin film transistor of the pixel unit is connected to an i-th gate line, and the gate of the second thin film transistor of the pixel unit is connected to an (i+1)-th gate line; 1≤i≤N. The step of turning on the first thin film transistor and the second thin film transistor of the pixel unit based on the voltage difference between the pixel electrode and the common electrode of each pixel unit, and charging the pixel electrode and the common electrode respectively includes: turning on the first thin film transistor of each pixel unit in a first row of pixel units through a first gate line; and charging the pixel electrode of each pixel unit in the first row of pixel units through a corresponding data line; based on a voltage difference between the pixel electrode and the common electrode of each pixel unit in the first row of pixel units to an (N−1)-th row of pixel units, and a voltage of the pixel electrode of each pixel unit in an (s−1)-th row of pixel units, determining a voltage of the pixel electrode and a voltage of the common electrode of each pixel unit in an s-th row of pixel units; turning on the first thin film transistor of each pixel unit in an s-th row of pixel units and the second thin film transistor of each pixel unit in the (s−1)-th row of pixel units through an s-th gate line; and charging the pixel electrode of each pixel unit in the s-th row of pixel units and the common electrode of each pixel unit in the (s−1)-th row of pixel units through a corresponding data line; s is an integer greater than 1 and less than N+1; based on a voltage difference between the pixel electrode and the common electrode of each pixel unit in the first row of pixel units to an N-th row of pixel units, and a voltage of the pixel electrode of each pixel unit in the N-th row of pixel units, determining a voltage of the common electrode of each pixel unit in an (N+1)-th row of pixel units; and turning on the second thin film transistor of each pixel unit in the N-th row of pixel units through an (N+1)-th gate line; and charging the common electrode of each pixel unit in the (N+1)-th row of pixel units through a corresponding data line.

In some embodiments of the present disclosure, the plurality of pixel units are arranged in an N×M array; the pixel structure further includes a plurality of gate lines and a plurality of data lines crossing each other to define a plurality of pixel regions; each pixel unit is located in a corresponding pixel region; a quantity of the gate lines is N+1, and a quantity of the data lines is M; for a pixel unit in an i-th row of pixel units, the gate of the second thin film transistor of the pixel unit is connected to an i-th gate line, and the gate of the first thin film transistor of the pixel unit is connected to an (i+1)-th gate line; 1≤i≤N. The step of turning on the first thin film transistor and the second thin film transistor of the pixel unit based on the voltage difference between the pixel electrode and the common electrode of each pixel unit, and charging the pixel electrode and the common electrode respectively includes: turning on the second thin film transistor of each pixel unit in a first row of pixel units through a first gate line; and charging the common electrode of each pixel unit in the first row of pixel units through a corresponding data line; based on a voltage difference between the pixel electrode and the common electrode of each pixel unit in the first row of pixel units to an (N−1)-th row of pixel units, and a voltage of the common electrode of each pixel unit in an (r−1)-th row of pixel units, determining a voltage of the pixel electrode and a voltage of the common electrode of each pixel unit in an r-th row of pixel units; turning on the second thin film transistor of each pixel unit in an r-th row of pixel units and the first thin film transistor of each pixel unit in the (r−1)-th row of pixel units through an r-th gate line; and charging the common electrode of each pixel unit in the r-th row of pixel units and the pixel electrode of each pixel unit in the (r−1)-th row of pixel units through a corresponding data line; r is an integer greater than 1 and less than N+1; based on a voltage difference between the pixel electrode and the common electrode of each pixel unit in the first row of pixel units to an N-th row of pixel units, and a voltage of the common electrode of each pixel unit in the N-th row of pixel units, determining a voltage of the pixel electrode of each pixel unit in an (N+1)-th row of pixel units; and turning on the first thin film transistor of each pixel unit in the N-th row of pixel units through an (N+1)-th gate line; and charging the pixel electrode of each pixel unit in the (N+1)-th row of pixel units through a corresponding data line.

In some embodiments of the present disclosure, an absolute value of the voltage difference between the pixel electrode and the common electrode of the pixel unit is in a range of 0V to 4V; a voltage charged to the pixel electrode through a corresponding first thin film transistor is in a range of 0V to 4V; and a voltage charged to the common electrode through a corresponding second thin film transistor is in a range of 0V to 4V.

An embodiment of the present disclosure further provides a method for manufacturing a pixel structure. The method includes: forming a first thin film transistor, a second thin film transistor, a pixel electrode, and a common electrode; a drain of the first thin film transistor being connected to the pixel electrode, and a drain of the second thin film transistor being connected to the common electrode.

In some embodiments of the present disclosure, the step of forming a first thin film transistor, a second thin film transistor, a pixel electrode, and a common electrode; a drain of the first thin film transistor being connected to the pixel electrode, and a drain of the second thin film transistor being connected to the common electrode includes: providing a basal substrate; forming a common electrode on the basal substrate; forming gate lines, a gate of the first thin film transistor, and a gate of the second thin film transistor on the basal substrate; the gate of the first thin film transistor and the gate of the second thin film transistor being respectively connected to corresponding gate lines; forming a gate insulating layer; the gate insulating layer covering the basal substrate, the gate lines, the gate of the first thin film transistor, the gate of the second thin film transistor, and the common electrode; forming an active layer of the first thin film transistor and an active layer of the second thin film transistor; forming a first via hole at a portion of the gate insulating layer corresponding to the common electrode; forming data lines, a source and a drain of the first thin film transistor, a source and a drain of the second thin film transistor; the source and the drain of the first thin film transistor being respectively in contact with the active layer of the first thin film transistor; the source and the drain of the second thin film transistor being respectively in contact with the active layer of the second thin film transistor; the drain of the second thin film transistor being connected to the common electrode through the first via hole; the source of the first thin film transistor and the source of the second thin film transistor being respectively connected to corresponding data lines; forming a passivation layer; the passivation layer covering the gate insulating layer, the data lines, the active layer, the source and the drain of the first thin film transistor, the active layer, the source and the drain of the second thin film transistor; forming a second via hole at a portion of the passivation layer corresponding to the drain of the first thin film transistor; and forming a pixel electrode on the passivation layer; the pixel electrode being connected to the drain of the first thin film transistor through the second via hole.

In some embodiments of the present disclosure, the step of forming a first thin film transistor, a second thin film transistor, a pixel electrode, and a common electrode; a drain of the first thin film transistor being connected to the pixel electrode, and a drain of the second thin film transistor being connected to the common electrode includes: providing a basal substrate; forming a common electrode on the basal substrate; forming gate lines, a gate of the first thin film transistor, and a gate of the second thin film transistor on the basal substrate; the gate of the first thin film transistor and the gate of the second thin film transistor being respectively connected to corresponding gate lines; forming a gate insulating layer; the gate insulating layer covering the basal substrate, the gate lines, the gate of the first thin film transistor, the gate of the second thin film transistor, and the common electrode; forming an active layer of the first thin film transistor and an active layer of the second thin film transistor; forming data lines, a source and a drain of the first thin film transistor, a source and a drain of the second thin film transistor; the source and the drain of the first thin film transistor being respectively in contact with the active layer of the first thin film transistor; the source and the drain of the second thin film transistor being respectively in contact with the active layer of the second thin film transistor; the source of the first thin film transistor and the source of the second thin film transistor being respectively connected to corresponding data lines; forming a passivation layer; the passivation layer covering the gate insulating layer, the data lines, the active layer, the source and the drain of the first thin film transistor, the active layer, the source and the drain of the second thin film transistor; forming a third via hole and a fourth via hole; the third via hole exposing the drain of the first thin film transistor; the fourth via hole exposing the common electrode and the drain of the second thin film transistor; and forming a pixel electrode and a conductive connection structure on the passivation layer; the pixel electrode being connected to the drain of the first thin film transistor through the third via hole; the conductive connection structure filling the fourth via hole, and being in contact with the common electrode and the drain of the second thin film transistor.

In some embodiments of the present disclosure, the step of forming a first thin film transistor, a second thin film transistor, a pixel electrode, and a common electrode; a drain of the first thin film transistor being connected to the pixel electrode, and a drain of the second thin film transistor being connected to the common electrode includes: providing a basal substrate; forming gate lines, a gate of the first thin film transistor, and a gate of the second thin film transistor on the basal substrate; the gate of the first thin film transistor and the gate of the second thin film transistor being respectively connected to corresponding gate lines; forming a gate insulating layer; the gate insulating layer covering the basal substrate, the gate lines, the gate of the first thin film transistor, and the gate of the second thin film transistor; forming, on the gate insulating layer, an active layer of the first thin film transistor and an active layer of the second thin film transistor; forming a pixel electrode on the passivation layer; forming data lines, a source and a drain of the first thin film transistor, a source and a drain of the second thin film transistor; the drain of the first thin film transistor being in contact with the pixel electrode; the source of the first thin film transistor and the source of the second thin film transistor being respectively connected to corresponding data lines; forming a passivation layer; the passivation layer covering the gate insulating layer, the data lines, the active layer, the source and the drain of the first thin film transistor, the active layer, the source and the drain of the second thin film transistor, and the pixel electrode; forming a fifth via hole at a portion of the passivation layer corresponding to the drain of the second thin film transistor; and forming a common electrode on the passivation layer; the common electrode being connected to the drain of the second thin film transistor through the fifth via hole.

### BRIEF DESCRIPTION OF THE DRAWINGS

In order to more clearly illustrate the technical solutions in embodiments of the disclosure or in the prior art, the appended drawings needed to be used in the description of the embodiments or the prior art will be introduced briefly in the following. Obviously, the drawings in the following description are only some embodiments of the disclosure, and for those of ordinary skills in the art, other drawings may be obtained according to these drawings under the premise of not paying out creative work.

FIG. 1 is a schematic diagram of a pixel structure according to an embodiment of the present disclosure;

FIG. 2 is a schematic diagram of a pixel structure according to another embodiment of the present disclosure;

FIG. 3 is a schematic diagram of charging the pixel electrodes and the common electrodes of the pixel units in the pixel structure of FIG. 1;

FIG. 4 is a schematic diagram showing a voltage difference between a pixel electrode and a common electrode in each pixel unit after charging the pixel electrodes and the common electrodes of the pixel units in the pixel structure of FIG. 3;

FIG. 5 is a flowchart of a method for driving a pixel structure according to an embodiment of the present disclosure;

FIG. 6 is a flowchart of a method for driving a pixel structure according to another embodiment of the present disclosure;

FIG. 7 is a flowchart of a method for driving a pixel structure according to yet another embodiment of the present disclosure;

FIG. 8 is a flowchart of a method for manufacturing a pixel structure according to an embodiment of the present disclosure;

FIG. 9 is a flowchart of a method for manufacturing a pixel structure according to another embodiment of the present disclosure;

FIG. 10 is a flowchart of a method for manufacturing a pixel structure according to yet another embodiment of the present disclosure; and

FIG. 11 is a flowchart of a method for manufacturing a pixel structure according to still another embodiment of the present disclosure.

### DETAILED DESCRIPTION OF THE DISCLOSURE

In the following, the technical solutions in embodiments of the disclosure will be described clearly and completely in connection with the drawings in the embodiments of the disclosure. Obviously, the described embodiments are only part of the embodiments of the disclosure, and not all of the embodiments. Based on the embodiments in the disclosure, all other embodiments obtained by those of ordinary skills in the art under the premise of not paying out creative work pertain to the protection scope of the disclosure.

In a typical pixel structure, a pixel unit includes a pixel electrode and a common electrode. By applying a voltage to the pixel electrode and the common electrode, a voltage difference is generated between the pixel electrode and the common electrode, and the brightness of the pixel unit is changed to realize display of the display device. When a voltage is applied to a common electrode, the same voltage is usually applied to all the common electrodes of the pixel units. However, due to the structural design limitation of the existing pixel structure, the voltages on the common electrodes of the pixel unit are uneven, thereby causing degradation of the display quality of the display device, for example, occurrence of defects such as flicker, greenish image, and residual image.

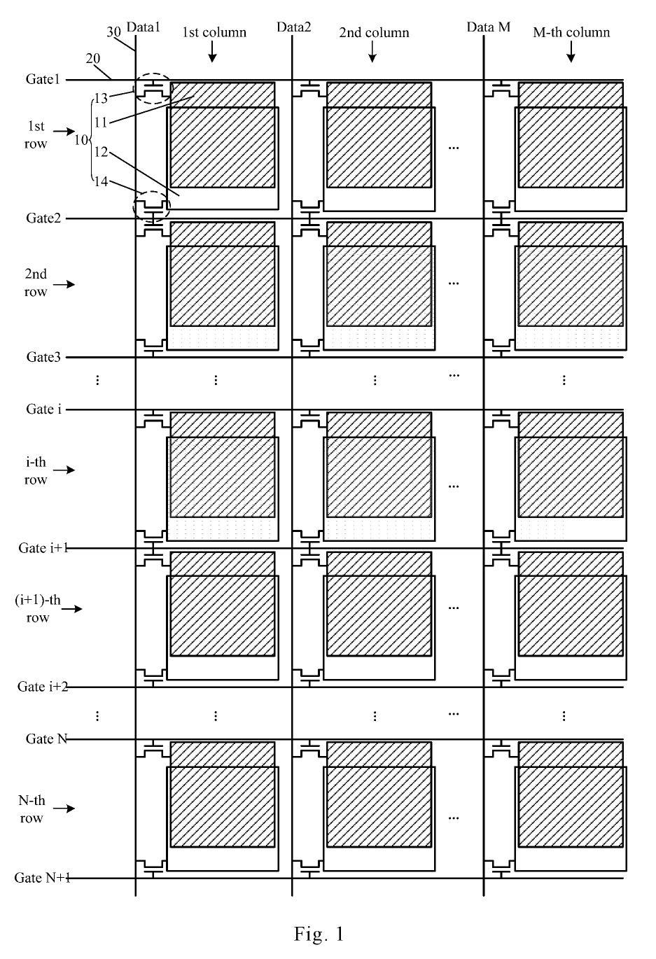

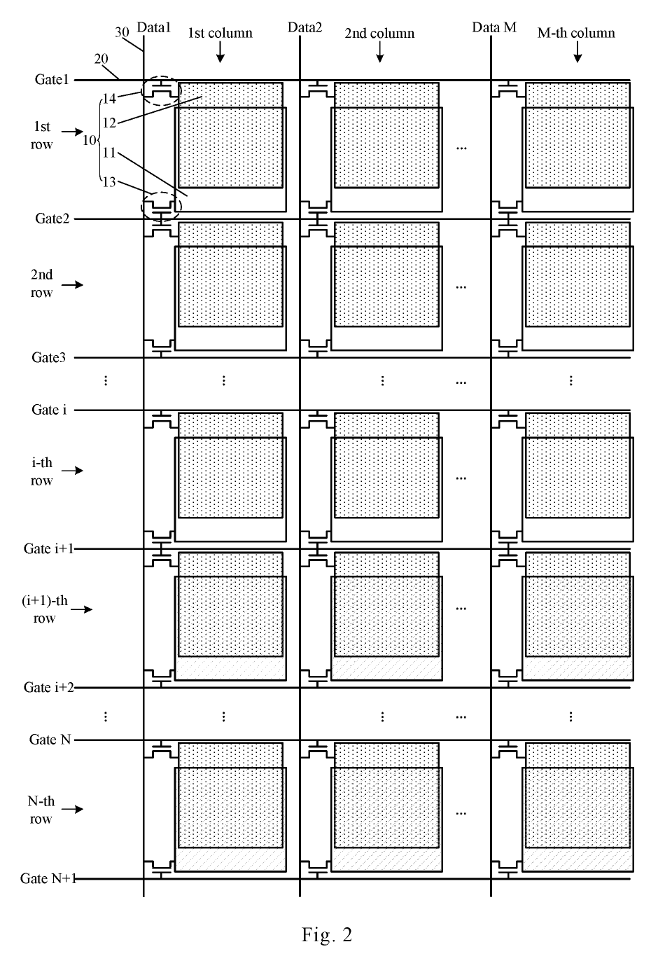

Referring to FIG. 1 or FIG. 2, a pixel structure provided by an embodiment of the present disclosure includes a plurality of pixel units 10. Each pixel unit 10 includes a first thin film transistor 13, a pixel electrode 11, and a common electrode 12; a drain of the first thin film transistor 13 of the pixel unit is connected to the pixel electrode 11 of the pixel unit; each one of at least a portion of the plurality of pixel units 10 further includes a second thin film transistor 14; a drain of the second thin film transistor 14 of the pixel unit is connected to the common electrode 12 of the pixel unit.

For example, referring to FIG. 1 or FIG. 2, the pixel structure provided by the embodiment of the present disclosure includes a plurality of pixel units 10, and the plurality of pixel units 10 may be arranged in an array. The arrangement of the plurality of pixel units 10 can be set according to the mode of the display panel.

For example, when the pixel structure provided by the embodiment of the present disclosure is applied to a display panel of an RGB (red, green, blue) mode, one third of the plurality of pixel units 10 are R (red) pixel units, which show red during displaying; one third of the plurality of pixel units 10 are G (green) pixel units, which show green during displaying; one third of the plurality of pixel units 10 are B (blue) pixel units, which show blue during displaying. An R pixel unit, a G pixel unit, and a B pixel unit together form a color display unit. In each color display unit, the arrangement of the R pixel unit, the G pixel unit, and the B pixel unit can be set according to actual needs. For example, the R pixel unit, the G pixel unit, and the B pixel unit may be sequentially disposed in the direction of the row.

For example, when the pixel structure provided by the embodiment of the present disclosure is applied to a display panel of an RGBW (red, green, blue, white) mode, a quarter of the pixel units 10 are R (red) pixel unit, which show red during displaying; a quarter of the pixel units 10 are G (green) pixel unit, which show green during displaying; a quarter of the pixel units 10 are B (blue) pixel unit, which show blue during displaying; a quarter of the pixel units 10 are W (white) pixel unit, which show white during displaying. An R pixel unit, a G pixel unit, a B pixel unit, and a W pixel unit together form a color display unit. In each color display unit, the arrangement of the R pixel unit, the G pixel unit, the B pixel unit, and the W pixel unit can be set according to actual needs.

With reference to FIG. 1 or FIG. 2, in the plurality of pixel units 10 in the pixel structure provided by the embodiment of the present disclosure, each pixel unit 10 includes a first thin film transistor 13, a pixel electrode 11, and a common electrode 12. In each pixel unit 10, the drain of the first thin film transistor 13 of the pixel unit 10 is connected to the pixel electrode 11 of the pixel unit 10. In this way, when the first thin film transistor 13 of the pixel unit 10 is turned on, the pixel electrode 11 of the pixel unit 10 can be charged.

Referring to FIG. 1 or FIG. 2, in the plurality of pixel units 10 in the pixel structure provided by an embodiment of the present disclosure, at least one pixel unit 10 further includes a second thin film transistor 14. The drain of the second thin film transistor 14 is connected to the common electrode 12 of the pixel unit 10. In this way, when the second thin film transistor 14 of the pixel unit 10 is turned on, the common electrode 12 of unit 10 can be charged. For example, in the plurality of pixel units 10, one pixel unit 10 further includes a second thin film transistor 14 having a drain connected to the common electrode 12 in the pixel unit 10, therefore, when the drain of the second thin film transistor 14 in the pixel unit 10 is turned on, the common electrode 12 in the pixel unit 10 can be charged to implement independent control on the voltage of the common electrode 12 of the pixel unit 10. Alternatively, in the plurality of pixel units 10, at least two pixel units 10 and not all of the pixel units 10 further include second thin film transistors 14; in the pixel unit 10 provided with the second thin film transistor 14, the drain of the second thin film transistor 14 is connected to the common electrode 12 of the pixel unit 10; when the second thin film transistor 14 in the pixel unit 10 is turned on, the common electrode 12 in the pixel unit 10 can be charged to implement independent control on the voltage of the common electrode 12 of this pixel unit 10. Alternatively, in the plurality of pixel units 10, each pixel unit 10 further includes a second thin film transistor 14; a drain of the second thin film transistor 14 of the pixel unit 10 is connected to the common electrode 12 of the pixel unit 10; when the second thin film transistor 14 in the pixel unit 10 is turned on, the common electrode 12 in the pixel unit 10 can be charged to implement independent control on the voltage of the common electrode 12 of this pixel unit 10. It should be noted that the number of the pixel units 10 provided with the second thin film transistor 14 can be set according to actual needs. Optionally, each one of the plurality of pixel units 10 includes a second thin film transistor 14 having a drain connected to the common electrode 12 of the pixel unit, so that independent control on the voltage of the common electrode 12 of each pixel unit 10 can be achieved.

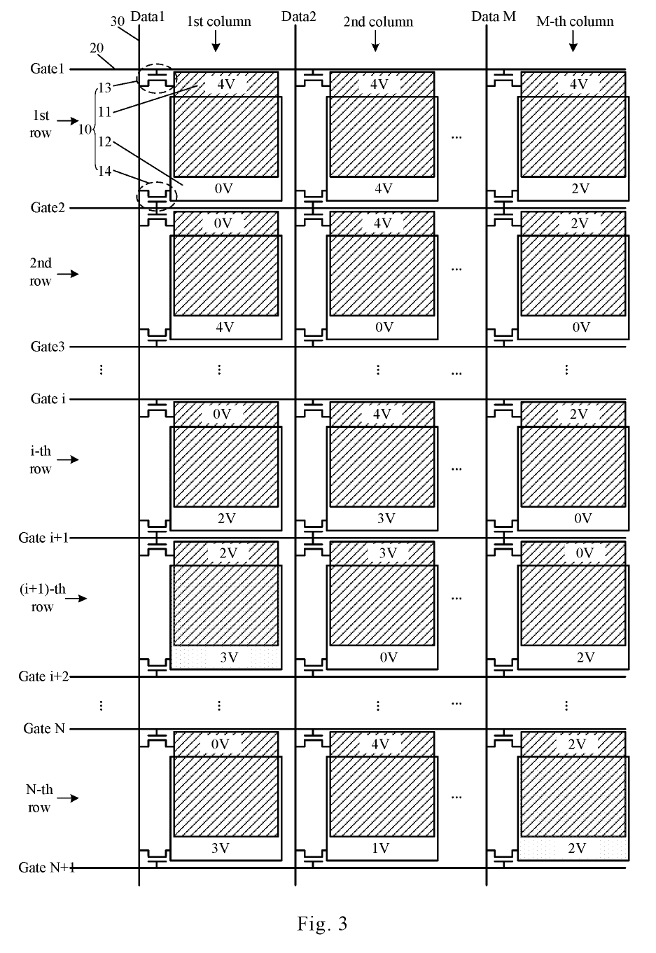

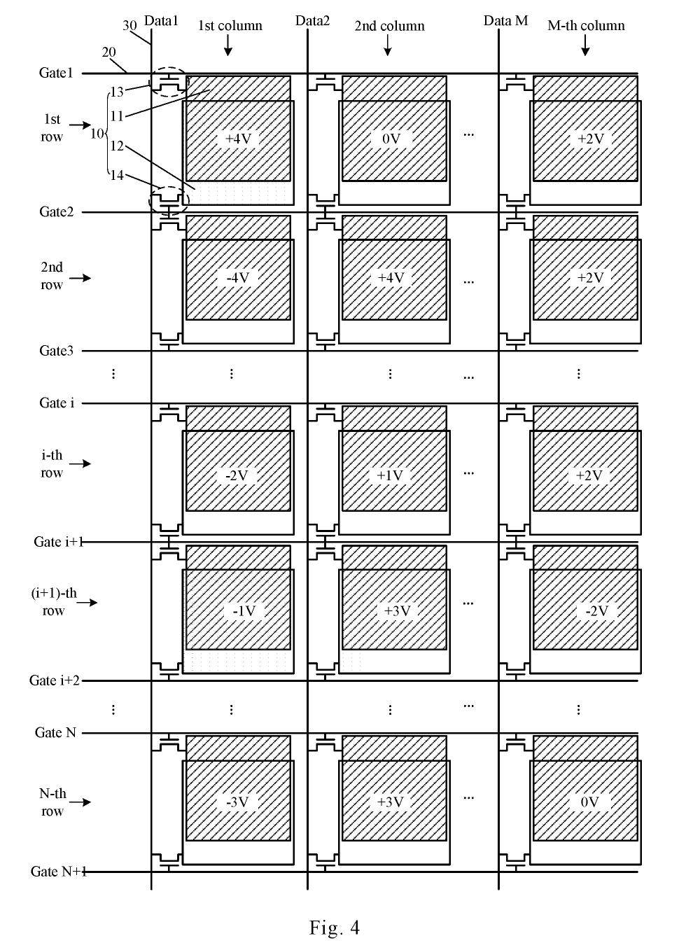

When the pixel structure provided by the embodiment of the present disclosure is working, referring to FIG. 3 and FIG. 4, the first thin film transistor 13 is turned on to charge the pixel electrode 11 connected to the first thin film transistor 13; the second thin film transistor 14 is turned on to charge the common electrode 12 connected to the second thin film transistor 14. In this way, a corresponding voltage difference between the pixel electrode 11 and the common electrode 12 is generated. The voltage difference generated between the pixel electrode 11 and the common electrode 12 drives the liquid crystal to deflect, so that the pixel unit 10 performs display to realize the displaying of the display device.

It can be seen from the above analysis that in the pixel structure provided by the embodiment of the present disclosure, the first thin film transistor 13 of the pixel unit 10 is connected to the pixel electrode 11 of the pixel unit 10, and the second thin film transistor 14 of the pixel unit 10 is connected to the common electrode 12 of the pixel unit 10. Therefore, when the first thin film transistor 13 is turned on, the pixel electrode 11 can be charged; when the second thin film transistor 14 is turned on, the common electrode 12 can be charged. When the displaying of the display device is realized, the first thin film transistor 13 and the second thin film transistor 14 may be turned on to charge the pixel electrode 11 and the common electrode 12, that is, the voltage of the pixel electrode 11 and the voltage of the common electrode 12 can be controlled respectively. In this way, the voltage difference between the pixel electrode 11 and the common electrode 12 in the pixel unit 10 matches the image to be displayed, thereby improving the display quality of the display device. Occurrence of defects such as flicker, greenish image, and residual image can thus be prevented.

In addition, in the related art, a plurality of pixel units in a pixel structure typically share one common electrode. When the display device is working, the common electrode is charged, and it can be understood that the voltage of the common electrode of all the pixel units is the same. A thin film transistor charges a corresponding pixel electrode, and a voltage difference is generated between the pixel electrode and the common electrode to drive the liquid crystal to deflect, so that the pixel unit performs display to realize display of the display device. Since the plurality of pixel units share one common electrode, the common electrode covers all of the pixel units, the area of the common electrode is relatively large. When charging the common electrode, since the area of the common electrode is relatively large, the film thickness and resistance of the regions of the common electrode are not uniform, and the voltages of the regions of the common electrode are thus different. Therefore, the voltage difference between the pixel electrode and the common electrode may not match the image to be displayed, degrading the picture display quality of the display device. In the pixel structure provided by the embodiment of the present disclosure, the pixel unit 10 has a separate common electrode 12, and the common electrode 12 can be charged when the second thin film transistor 14 is turned on, thereby independently controlling the voltage of the common electrode 12. The case where the voltage difference between the pixel electrode 11 and the common electrode 12 does not match the image to be displayed due to the structure and performance problems of the common electrode 12 can thus be avoided.

Moreover, in the related art, a plurality of pixel units in a pixel structure typically share one common electrode. When the display device is working, the common electrode is charged, and it can be understood that the voltage of the common electrode of all the pixel units is the same. For example, for an HADS (high aperture advanced super dimension switch) display such as a notebook, the common electrode is typically charged with a voltage of 4V. The absolute value of the voltage difference between the pixel electrode and the common electrode required for liquid crystal deflection in the notebook type HADS display device is 0V˜4V. Considering the polarity reversal of the liquid crystal, it is usually necessary to charge the pixel electrode with a voltage of 0V˜8V. When a higher voltage (e.g., a voltage greater than 4V, such as 8V) is applied to the pixel electrode, it is usually necessary to use an amplifier in the driving chip for amplification, resulting in an increase in power consumption of the driving chip. In the pixel structure provided by the embodiment of the present disclosure, since the voltage of the pixel electrode 11 and the voltage of the common electrode 12 of each pixel unit 10 can be separately controlled (referring to FIG. 3), the voltage charged to the pixel electrode 11 and the common electrode can be set to 0V˜4V, so that the absolute value of the voltage difference between the pixel electrode 11 and the common electrode 12 is 0V˜4V (referring to FIG. 4). Compared with the related art, in the pixel structure provided by the embodiment of the present disclosure, the voltages respectively charged to the pixel electrode 11 and the common electrode 12 are low, so that it is not necessary to use an amplifier in the driving chip for amplification, thereby reducing the power consumption of the driving chip.

In the above embodiment, the arrangement of the pixel electrode 11 and the common electrode 12 can be set according to the type of the display device. For example, if the display device is a TN (twisted nematic) display device, the display panel is a TN display panel. In this case, the display panel includes a first basal substrate and a second basal substrate which are oppositely disposed, the pixel electrode 11 is disposed on the first basal substrate, and the common electrode 12 is disposed on the second basal substrate. The first thin film transistor 13 is disposed on the first basal substrate and connected to the pixel electrode 11; the second thin film transistor 14 is disposed on the second basal substrate and connected to the common electrode 12.

In some embodiments, the pixel structure further includes a basal substrate; the first thin film transistor 13, the second thin film transistor 14, the pixel electrode 11, and the common electrode 12 are all located on the same basal substrate. For example, the common electrode 12 and the second thin film transistor 14 may be integrated on the array substrate. At this time, the first thin film transistor 13, the second thin film transistor 14, the pixel electrode 11, and the common electrode 12 are all located on the same substrate and on the same side of the substrate. In this case, the display device may be an ADS (advanced super dimension switch) display device, an HADS display device, or the like. With such a design, it is convenient to charge the pixel electrode 11 and the common electrode 12 respectively through the first thin film transistor 13 and the second thin film transistor 14 by using a driving chip.

In the above embodiment, in order to control the on-state and the off-state of the first thin film transistor 13 and the second thin film transistor 14, a first gate line connected to the first thin film transistor 13 and a second gate line connected to the second thin film transistor 14 may be arranged. In this way, a control signal can be supplied to the first thin film transistor 13 through the first gate line connected to the first thin film transistor 13, thereby controlling the on-state and the off-state of the first thin film transistor 13; a control signal can be supplied to the second thin film transistor 14 through the second gate line connected to the second thin film transistor 14, thereby controlling the on-state and the off-state of the second thin film transistor 14; the pixel electrode 11 and the common electrode 12 can thus be charged. In practical applications, it is also possible to control the on-state and the off-state of the first thin film transistor 13 and the second thin film transistor 14 in other manners.

For example, referring to FIG. 1, in the pixel structure provided by the embodiment of the present disclosure, the plurality of pixel units 10 are arranged in an N×M array; the pixel structure further includes a plurality of gate lines 20 and a plurality of data lines 30 crossing each other to define a plurality of pixel regions; each pixel unit 10 is located in a corresponding pixel region; a quantity of the gate lines 20 is N+1, and a quantity of the data lines 30 is M; for a pixel unit 10 in an i-th row of pixel units 10, the gate of the first thin film transistor 13 of the pixel unit 10 is connected to an i-th gate line 20, and the gate of the second thin film transistor 14 of the pixel unit 10 is connected to an (i+1)-th gate line 20; 1≤i≤N. That is, as shown in FIG. 1, the first gate line 20 (shown as Gate 1 in FIG. 1) controls the on-state and the off-state of the first thin film transistor 13 of each pixel unit 10 in the first row of pixel units 10; the (N+1)-th gate line 20 (shown as Gate N+1 in FIG. 1) controls the on-state and the off-state of the second thin film transistor 14 of each pixel unit 10 in the N-th row of pixel units 10. For the second gate line 20 (shown as Gate 2 in FIG. 1) to the N-th gate line 20 (shown as Gate N in FIG. 1), each gate line 20 can control the on-state and the off-state of the second thin film transistor 14 of each pixel unit 10 in the row of pixel units 10 located on the upper side of this gate line 20, and this gate line 20 can also control the on-state and the off-state of the first thin film transistor 13 of each pixel unit 10 in the row of pixel units 10 located on the lower side of this gate line 20.

In this case, as shown in FIG. 3, when charging the pixel electrode 11 and the common electrode 12 respectively, the first thin film transistor 13 of each pixel unit 10 in the first row of pixel units 10 is turned on by the first gate line 20 (shown as Gate 1 in FIG. 3), so that the pixel electrode 11 of each pixel unit 10 in the first row of pixel units 10 can be charged. The second thin film transistor 14 of each pixel unit 10 in the first row of pixel units 10 and the first thin film transistor 13 of each pixel unit 10 in the second row of pixel units 10 are turned on by the second gate line 20 (Gate 2 shown in FIG. 3), so that the common electrode 12 of each pixel unit 10 in the first row of pixel units 10 can be charged, and the pixel electrode 11 of each pixel unit 10 in the second row of pixel units 10 can be charged. The second thin film transistor 14 of each pixel unit 10 in the second row of pixel units 10 and the first thin film transistor 13 of each pixel unit 10 in the third row of pixel units 10 are turned on by the third gate line 20 (Gate 3 shown in FIG. 3), so that the common electrode 12 of each pixel unit 10 in the second row of pixel units 10 can be charged, and the pixel electrode 11 of each pixel unit 10 in the third row of pixel units 10 can be charged. This operation is performed for the gate lines sequentially. The second thin film transistor 14 of each pixel unit 10 in the (N−1)-th row of pixel units 10 and the first thin film transistor 13 of each pixel unit 10 in the N-th row of pixel units 10 are turned on by the N-th gate line 20 (Gate N shown in FIG. 3), so that the common electrode 12 of each pixel unit 10 in the (N−1)-th row of pixel units 10 can be charged, and the pixel electrode 11 of each pixel unit 10 in the N-th row of pixel units 10 can be charged. The second thin film transistor 14 of each pixel unit 10 in the N-th row of pixel units 10 is turned on by the (N+1)-th gate line 20 (shown as Gate N+1 in FIG. 3), so that the common electrode 12 of each pixel unit 10 in the N-th row of pixel units 10 can be charged.

Alternatively, referring to FIG. 2, in the pixel structure provided by the embodiment of the present disclosure, the plurality of pixel units 10 are arranged in an N×M array; the pixel structure further includes a plurality of gate lines 20 and a plurality of data lines 30 crossing each other to define a plurality of pixel regions; each pixel unit 10 is located in a corresponding pixel region; a quantity of the gate lines 20 is N+1, and a quantity of the data lines 30 is M; for a pixel unit in an i-th row of pixel units 10, the gate of the second thin film transistor 14 of the pixel unit 10 is connected to an i-th gate line 20, and the gate of the first thin film transistor 13 of the pixel unit 10 is connected to an (i+1)-th gate line 20; 1≤i≤N. That is, as shown in FIG. 2, the first gate line 20 (shown as Gate 1 in FIG. 2) controls the on-state and the off-state of the second thin film transistor 14 of each pixel unit 10 in the first row of pixel units 10; the (N+1)-th gate line 20 (shown as Gate N+1 in FIG. 2) controls the on-state and the off-state of the first thin film transistor 13 of each pixel unit 10 in the N-th row of pixel units 10. For the second gate line 20 (shown as Gate 2 in FIG. 2) to the N-th gate line 20 (shown as Gate N in FIG. 2), each gate line 20 can control the on-state and the off-state of the first thin film transistor 13 of each pixel unit 10 in the row of pixel units 10 located on the upper side of this gate line 20, and this gate line 20 can also control the on-state and the off-state of the second thin film transistor 14 of each pixel unit 10 in the row of pixel units 10 located on the lower side of this gate line 20.

In this case, when charging the pixel electrode 11 and the common electrode 12 respectively, the second thin film transistor 14 of each pixel unit 10 in the first row of pixel units 10 is turned on by the first gate line 20 (shown as Gate 1 in FIG. 2), so that the common electrode 12 of each pixel unit 10 in the first row of pixel units 10 can be charged. The first thin film transistor 13 of each pixel unit 10 in the first row of pixel units 10 and the second thin film transistor 14 of each pixel unit 10 in the second row of pixel units 10 are turned on by the second gate line 20 (Gate 2 shown in FIG. 2), so that the pixel electrode 11 of each pixel unit 10 in the first row of pixel units 10 can be charged, and the common electrode 12 of each pixel unit 10 in the second row of pixel units 10 can be charged. The first thin film transistor 13 of each pixel unit 10 in the second row of pixel units 10 and the second thin film transistor 14 of each pixel unit 10 in the third row of pixel units 10 are turned on by the third gate line 20 (Gate 3 shown in FIG. 2), so that the pixel electrode 11 of each pixel unit 10 in the second row of pixel units 10 can be charged, and the common electrode 12 of each pixel unit 10 in the third row of pixel units 10 can be charged. This operation is performed for the gate lines sequentially. The first thin film transistor 13 of each pixel unit 10 in the (N−1)-th row of pixel units 10 and the second thin film transistor 14 of each pixel unit 10 in the N-th row of pixel units 10 are turned on by the N-th gate line 20 (Gate N shown in FIG. 2), so that the pixel electrode 11 of each pixel unit 10 in the (N−1)-th row of pixel units 10 can be charged, and the common electrode 12 of each pixel unit 10 in the N-th row of pixel units 10 can be charged. The first thin film transistor 13 of each pixel unit 10 in the N-th row of pixel units 10 is turned on by the (N+1)-th gate line 20 (shown as Gate N+1 in FIG. 2), so that the pixel electrode 11 of each pixel unit 10 in the N-th row of pixel units 10 can be charged.

Referring to FIG. 1 and FIG. 2, the on-state and off-state of the first thin film transistor 13 and the second thin film transistor 14 are controlled by the same set of gate lines 20 without arranging a first gate line connected to the first thin film transistor 13 and a second gate line connected to the second thin film transistor 14. In this way, the number of the gate lines 20 can be reduced, thereby increasing the aperture ratio of the display device.

In the above embodiments, when charging the pixel electrode 11 and the common electrode 12 respectively, a first data line connected to the first thin film transistor 13 and a second data line connected to the second thin film transistor 14 may be arranged. In order to charge the pixel electrode 11 and the common electrode 12, the first thin film transistor 13 is turned on, and a signal is input to the first thin film transistor 13 through the first data line connected to the first thin film transistor 13, thereby charging the pixel electrode 11; the second thin film transistor 14 is turned on, and a signal is input to the second thin film transistor 14 through the second data line connected to the second thin film transistor 14, thereby charging the common electrode 12.

In practical applications, when charging the pixel electrode 11 and the common electrode 12 respectively, other methods may also be employed. For example, referring to FIG. 1 or FIG. 2, for a pixel unit 10 in a j-th column of pixel units, a source of the first thin film transistor 13 of the pixel unit 10 is connected to a j-th data line 30; a drain of the first thin film transistor 13 of the pixel unit 10 is connected to a pixel electrode 11; a source of the second thin film transistor 14 of the pixel unit 10 is connected to the j-th data line 30; a drain of the second thin film transistor 14 of the pixel unit 10 is connected to a common electrode 12; 1≤j≤M. That is, the source of the first thin film transistor 13 and the source of the second thin film transistor 14 of each pixel unit 10 in each column of pixel units 10 are connected to the data line 30 corresponding to the column of pixel units 10. Signals can be input to the first thin film transistor 13 and the second thin film transistor 14 through the corresponding data line 30, thus the pixel electrode 11 and the common electrode 12 can be respectively charged.

Referring to FIG. 3, the structure shown in FIG. 1 is taken as an example for the pixel structure, and the manner in which the pixel electrode 11 and the common electrode 12 are respectively charged is described below in detail. The driving chip first determines the voltage difference between the pixel electrode 11 and the common electrode 12 of each pixel unit 10 based on the image to be displayed. Then, the first thin film transistor 13 of each pixel unit 10 in the first row of pixel units 10 is turned on by the first gate line 20 (shown as Gate 1 in FIG. 3), and voltages (within a range of 0V to 4V) are charged to the pixel electrodes 11 of the pixel units 10 in the first row of pixel units 10 through the respective gate lines 20 (Data 1 to Data M shown in FIG. 3). For example, the pixel electrode 11 of the pixel unit 10 located in the first row and the first column in FIG. 3 is charged with a voltage of 4V; the pixel electrode 11 of the pixel unit 10 located in the first row and the second column in FIG. 3 is charged with a voltage of 4V; the pixel electrode 11 of the pixel unit 10 located in the first row and the M-th column in FIG. 3 is charged with a voltage of 4V. Then, based on the voltage difference between the pixel electrode 11 and the common electrode 12 of each pixel unit 10 in the first row of pixel units, and the voltage of the pixel electrode 11 of each pixel unit 10 in the first row of pixel units in FIG. 3, the voltage to be charged to the common electrode 12 of each pixel unit 10 in the first row of pixel units can be determined. The second thin film transistor 14 of each pixel unit 10 in the first row of pixel units 10 and the first thin film transistor 13 of each pixel unit 10 in the second row of pixel units 10 are turned on by the second gate line 20 (shown as Gate 2 in FIG. 3).

The common electrodes 12 of the pixel units 10 in the first row of pixel units 10 and the pixel electrodes 11 of the pixel units 10 in the second row of pixel units 10 are charged with corresponding voltages through the respective data lines 30 (shown as Data 1 to Data M in FIG. 3). For example, the voltage difference between the pixel electrode 11 and the common electrode 12 of the pixel unit 10 located in the first row and the first column in FIG. 3 is +4V, and the voltage of the pixel electrode 11 of the pixel unit 10 located in the first row and the first column is 4V; then the common electrode 12 of the pixel unit 10 located in the first row and the first column and the pixel electrode 11 of the pixel unit 10 located in the second row and the first column in FIG. 3 are charged with a voltage of 0V. The voltage difference between the pixel electrode 11 and the common electrode 12 of the pixel unit 10 located in the first row and the second column in FIG. 3 is 0V, and the voltage of the pixel electrode 11 of the pixel unit 10 located in the first row and the second column is 4V; then the common electrode 12 of the pixel unit 10 located in the first row and the second column and the pixel electrode 11 of the pixel unit 10 located in the second row and the second column in FIG. 3 are charged with a voltage of 4V. The voltage difference between the pixel electrode 11 and the common electrode 12 of the pixel unit 10 located in the first row and the M-th column in FIG. 3 is +2V, and the voltage of the pixel electrode 11 of the pixel unit 10 located in the first row and the M-th column is 4V; then the common electrode 12 of the pixel unit 10 located in the first row and the M-th column and the pixel electrode 11 of the pixel unit 10 located in the second row and the M-th column in FIG. 3 are charged with a voltage of 2V.

In this way, as shown in FIG. 4, the voltage difference between the pixel electrode 11 and the common electrode 12 of the pixel unit 10 located in the first row and the first column in FIG. 4 is +4V; the voltage difference between the pixel electrode 11 and the common electrode 12 of the pixel unit 10 located in the first row and the second column in FIG. 4 is 0V; the voltage difference between the pixel electrode 11 and the common electrode 12 of the pixel unit 10 located in the first row and the M-th column in FIG. 4 is +2V, therefore each pixel unit 10 located in the first row of pixel units 10 can display a corresponding gray scale. Then, based on the voltage difference between the pixel electrode 11 and the common electrode 12 of each pixel unit 10 in the second row of pixel units, and the voltage of the pixel electrode 11 of each pixel unit 10 in the second row of pixel units in FIG. 3, the voltages to be charged to the common electrodes 12 of the pixel units 10 in the second row of pixel units can be determined. The to make the pixel unit 10 of the second row of pixel units 10 The second thin film transistor 14 of each pixel unit 10 in the second row of pixel units and the first thin film transistor 13 of each pixel unit 10 in the third row of pixel units are turned on through the third gate line 20 (shown as Gate 2 in FIG. 3). The common electrode 12 of each pixel unit 10 in the second row of pixel units and the pixel electrode 11 of each pixel unit 10 in the third row of pixel units are charged with corresponding voltages through the respective data lines 30 (Data 1 to Data M shown in FIG. 3).

For example, the voltage difference between the pixel electrode 11 and the common electrode 12 of the pixel unit 10 located in the second row and the first column in FIG. 3 is −4V, and the voltage of the pixel electrode 11 of the pixel unit 10 located in the second row and the first column is 0V; then the common electrode 12 of the pixel unit 10 located in the second row and the first column and the pixel electrode 11 of the pixel unit 10 located in the third row and the first column in FIG. 3 are charged with a voltage of 0V. The voltage difference between the pixel electrode 11 and the common electrode 12 of the pixel unit 10 located in the second row and the second column in FIG. 3 is +4V, and the voltage of the pixel electrode 11 of the pixel unit 10 located in the second row and the second column is 4V; then the common electrode 12 of the pixel unit 10 located in the second row and the second column and the pixel electrode 11 of the pixel unit 10 located in the third row and the second column in FIG. 3 are charged with a voltage of 0V. The voltage difference between the pixel electrode 11 and the common electrode 12 of the pixel unit 10 located in the second row and the M-th column in FIG. 3 is +2V, and the voltage of the pixel electrode 11 of the pixel unit 10 located in the second row and the M-th column is 2V; then the common electrode 12 of the pixel unit 10 located in the second row and the M-th column and the pixel electrode 11 of the pixel unit 10 located in the third row and the M-th column in FIG. 3 are charged with a voltage of 0V.

In this way, as shown in FIG. 4, the voltage difference between the pixel electrode 11 and the common electrode 12 of the pixel unit 10 located in the second row and the first column in FIG. 4 is −4V; the voltage difference between the pixel electrode 11 and the common electrode 12 of the pixel unit 10 located in the second row and the second column in FIG. 4 is +4V; the voltage difference between the pixel electrode 11 and the common electrode 12 of the pixel unit 10 located in the second row and the M-th column in FIG. 4 is +2V, therefore each pixel unit 10 located in the second row of pixel units 10 can display a corresponding gray scale. The respective first thin film transistors 13 and second thin film transistors 14 are turned on in turn through the corresponding gate lines 20, and signals are transmitted to the first thin film transistors 13 and the second thin film transistor 14 through respective data lines 30 (shown as Data 1 to Data M in FIG. 3), thereby realizing charging of the pixel electrode 11 and the common electrode 12 of each pixel unit 10. Therefore, a desired voltage difference is generated between the pixel electrode 11 and the common electrode 12 of each pixel unit 10, each pixel unit 10 displays a corresponding gray scale, and the display device displays a corresponding image, thereby realizing display of the display device.

With such a design, when the pixel electrode 11 and the common electrode 12 are respectively charged, the signals are transmitted to the corresponding first thin film transistor 13 and the second thin film transistor 14 through the same set of data lines 30 without arranging a first data line connected to the first thin film transistor 13 and a second data line connected to the second thin film transistor 14. In this way, the number of the data lines 30 can be reduced, thereby increasing the aperture ratio of the display device.

An embodiment of the present disclosure further provides a display device including the pixel structure according to any one of the above-mentioned embodiments.

The display device may be any product or component having a display function, such as a liquid crystal display panel, an electronic paper, an OLED panel, a mobile phone, a tablet computer, a television, a display, a notebook computer, a digital photo frame, a navigator, and the like. The display device and the above-mentioned pixel structure have the same advantages compared with the prior art, which are not described herein again.

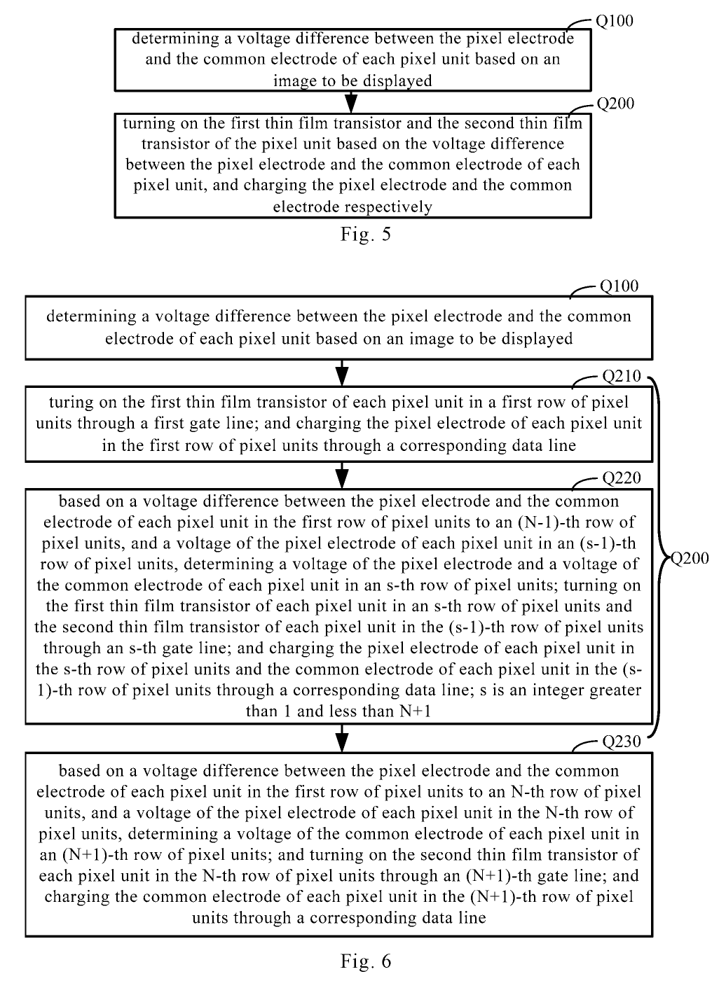

Referring to FIG. 5, an embodiment of the present disclosure further provides a method for driving the pixel structure according to any one of the above-mentioned embodiments. The method for driving the pixel structure includes the following steps.

Step Q100, determining a voltage difference between the pixel electrode and the common electrode of each pixel unit based on an image to be displayed.

Step Q200, turning on the first thin film transistor and the second thin film transistor of the pixel unit based on the voltage difference between the pixel electrode and the common electrode of each pixel unit, and charging the pixel electrode and the common electrode respectively.

The various embodiments in the specification are described in a progressive manner. The same or similar parts between the various embodiments may be referred to each other, and each embodiment focuses on the differences from the other embodiments. In particular, for the embodiment of the driving method, since it is basically similar to the embodiment of the pixel structure, the description is relatively simple, and the relevant part can be referred to the description of the embodiment of the pixel structure.

When the pixel structure shown in FIG. 1 is applied, referring to FIG. 6, step Q200 of turning on the first thin film transistor and the second thin film transistor of the pixel unit based on the voltage difference between the pixel electrode and the common electrode of each pixel unit, and charging the pixel electrode and the common electrode respectively may include the following steps.

Step Q210, turning on the first thin film transistor of each pixel unit in a first row of pixel units through a first gate line; and charging the pixel electrode of each pixel unit in the first row of pixel units through a corresponding data line.

Step Q220, based on a voltage difference between the pixel electrode and the common electrode of each pixel unit in the first row of pixel units to an (N−1)-th row of pixel units, and a voltage of the pixel electrode of each pixel unit in an (s−1)-th row of pixel units, determining a voltage of the pixel electrode and a voltage of the common electrode of each pixel unit in an s-th row of pixel units; turning on the first thin film transistor of each pixel unit in an s-th row of pixel units and the second thin film transistor of each pixel unit in the (s−1)-th row of pixel units through an s-th gate line; and charging the pixel electrode of each pixel unit in the s-th row of pixel units and the common electrode of each pixel unit in the (s−1)-th row of pixel units through a corresponding data line; s is an integer greater than 1 and less than N+1.

Step Q230, based on a voltage difference between the pixel electrode and the common electrode of each pixel unit in the first row of pixel units to an N-th row of pixel units, and a voltage of the pixel electrode of each pixel unit in the N-th row of pixel units, determining a voltage of the common electrode of each pixel unit in an (N+1)-th row of pixel units; and turning on the second thin film transistor of each pixel unit in the N-th row of pixel units through an (N+1)-th gate line; and charging the common electrode of each pixel unit in the (N+1)-th row of pixel units through a corresponding data line.

When the pixel structure shown in FIG. 2 is applied, referring to FIG. 7, step Q200 of turning on the first thin film transistor and the second thin film transistor of the pixel unit based on the voltage difference between the pixel electrode and the common electrode of each pixel unit, and charging the pixel electrode and the common electrode respectively may include the following steps.

Step Q240, turning on the second thin film transistor of each pixel unit in a first row of pixel units through a first gate line; and charging the common electrode of each pixel unit in the first row of pixel units through a corresponding data line.

Step Q250, based on a voltage difference between the pixel electrode and the common electrode of each pixel unit in the first row of pixel units to an (N−1)-th row of pixel units, and a voltage of the common electrode of each pixel unit in an (r−1)-th row of pixel units, determining a voltage of the pixel electrode and a voltage of the common electrode of each pixel unit in an r-th row of pixel units; turning on the second thin film transistor of each pixel unit in an r-th row of pixel units and the first thin film transistor of each pixel unit in the (r−1)-th row of pixel units through an r-th gate line; and charging the common electrode of each pixel unit in the r-th row of pixel units and the pixel electrode of each pixel unit in the (r−1)-th row of pixel units through a corresponding data line; r is an integer greater than 1 and less than N+1.

Step Q260, based on a voltage difference between the pixel electrode and the common electrode of each pixel unit in the first row of pixel units to an N-th row of pixel units, and a voltage of the common electrode of each pixel unit in the N-th row of pixel units, determining a voltage of the pixel electrode of each pixel unit in an (N+1)-th row of pixel units; and turning on the first thin film transistor of each pixel unit in the N-th row of pixel units through an (N+1)-th gate line; and charging the pixel electrode of each pixel unit in the (N+1)-th row of pixel units through a corresponding data line.

It is to be noted that, in step Q200, when the first thin film transistors and the second thin film transistors are turned on through the first gate line to the (N+1)-th gate line, an existing scanning method may be used. That is, the respective first thin film transistors and second thin film transistors are turned on in turn through the first gate line to the (N+1)-th gate line, thereby charging the corresponding pixel electrodes and the common electrodes.

When the pixel structure is applied to an HADS display device, an absolute value of the voltage difference between the pixel electrode and the common electrode of the pixel unit is in a range of 0V to 4V; a voltage charged to the pixel electrode through a corresponding first thin film transistor is in a range of 0V to 4V; a voltage charged to the common electrode through a corresponding second thin film transistor is in a range of 0V to 4V.

It should be noted that the absolute value of the voltage difference between the pixel electrode and the common electrode of the pixel unit differs depending on the pixel structure applied to the certain type of display devices (for example, ADS display devices, TN display devices, etc.). Correspondingly, the voltage charged to the pixel electrode through the first thin film transistor differs according to the pixel structure applied to the certain type of display devices, and the voltage charged to the common electrode through the second thin film transistor also differs according to the pixel structure applied to the certain type of display devices.

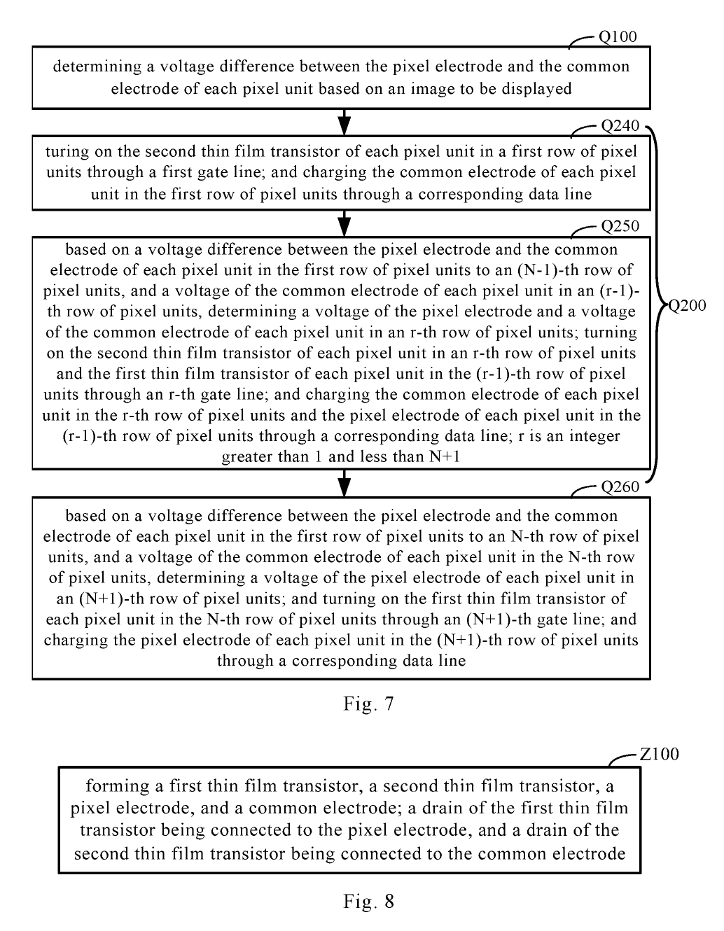

Referring to FIG. 8, an embodiment of the present disclosure further provides a method for manufacturing the pixel structure according to the above-mentioned embodiment. The method includes the following step.

Step Z100, forming a first thin film transistor, a second thin film transistor, a pixel electrode, and a common electrode; a drain of the first thin film transistor being connected to the pixel electrode, and a drain of the second thin film transistor being connected to the common electrode.

The various embodiments in the specification are described in a progressive manner. The same or similar parts between the various embodiments may be referred to each other, and each embodiment focuses on the differences from the other embodiments. In particular, for the embodiment of the manufacturing method, since it is basically similar to the embodiment of the pixel structure, the description is relatively simple, and the relevant part can be referred to the description of the embodiment of the pixel structure.

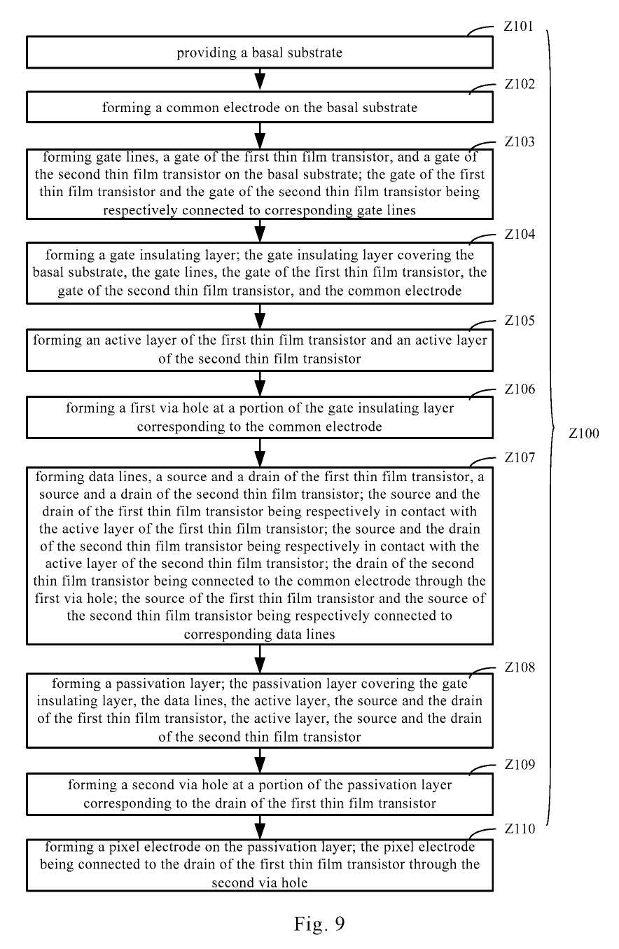

When the pixel structure is applied to an ADS display device, referring to FIG. 9, step Z100 of forming a first thin film transistor, a second thin film transistor, a pixel electrode, and a common electrode; a drain of the first thin film transistor being connected to the pixel electrode, and a drain of the second thin film transistor being connected to the common electrode may include the following steps.

Step Z101, providing a basal substrate.

Step Z102, forming a common electrode on the basal substrate.

Step Z103, forming gate lines, a gate of the first thin film transistor, and a gate of the second thin film transistor on the basal substrate; the gate of the first thin film transistor and the gate of the second thin film transistor being respectively connected to corresponding gate lines.

Step Z104, forming a gate insulating layer; the gate insulating layer covering the basal substrate, the gate lines, the gate of the first thin film transistor, the gate of the second thin film transistor, and the common electrode.

Step Z105, forming an active layer of the first thin film transistor and an active layer of the second thin film transistor.

Step Z106, forming a first via hole at a portion of the gate insulating layer corresponding to the common electrode.

Step Z107, forming data lines, a source and a drain of the first thin film transistor, a source and a drain of the second thin film transistor; the source and the drain of the first thin film transistor being respectively in contact with the active layer of the first thin film transistor; the source and the drain of the second thin film transistor being respectively in contact with the active layer of the second thin film transistor; the drain of the second thin film transistor being connected to the common electrode through the first via hole; the source of the first thin film transistor and the source of the second thin film transistor being respectively connected to corresponding data lines.

Step Z108, forming a passivation layer; the passivation layer covering the gate insulating layer, the data lines, the active layer, the source and the drain of the first thin film transistor, the active layer, the source and the drain of the second thin film transistor.

Step Z109, forming a second via hole at a portion of the passivation layer corresponding to the drain of the first thin film transistor.

Step Z110, forming a pixel electrode on the passivation layer; the pixel electrode being connected to the drain of the first thin film transistor through the second via hole.

In the above embodiment, in order to connect the pixel electrode to the drain of the first thin film transistor and connect the common electrode to the drain of the second thin film transistor, the first via hole is formed in the gate insulating layer by a patterning process, and the second via hole is formed in the passivation layer by a patterning process.

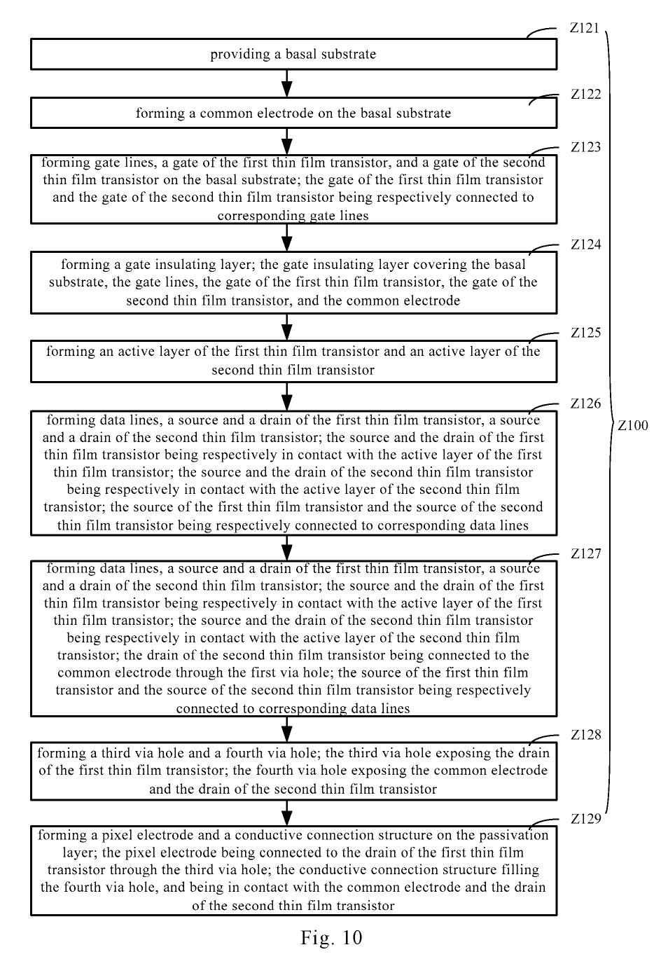

In practical applications, after forming the passivation layer, two via holes may be simultaneously formed by one patterning process, one via hole exposing the drain of the first thin film transistor, and the other via hole exposing the common electrode and the drain of the second thin film transistor. Then, a conductive connection structure filling the via hole exposing the common electrode and the drains of the second thin film transistor is formed while forming the pixel electrode, the pixel electrode is thus connected to the drain of the first thin film transistor, and the common electrode is thus connected to the drain of the second thin film transistor. In this way, the process steps for manufacturing the pixel structure are reduced, the efficiency is improved, and the cost is reduced. Specifically, referring to FIG. 10, step Z100 of forming a first thin film transistor, a second thin film transistor, a pixel electrode, and a common electrode; a drain of the first thin film transistor being connected to the pixel electrode, and a drain of the second thin film transistor being connected to the common electrode may include the following steps.

Step Z121, providing a basal substrate.

Step Z122, forming a common electrode on the basal substrate.

Step Z123, forming gate lines, a gate of the first thin film transistor, and a gate of the second thin film transistor on the basal substrate; the gate of the first thin film transistor and the gate of the second thin film transistor being respectively connected to corresponding gate lines.

Step Z124, forming a gate insulating layer; the gate insulating layer covering the basal substrate, the gate lines, the gate of the first thin film transistor, the gate of the second thin film transistor, and the common electrode.

Step Z125, forming an active layer of the first thin film transistor and an active layer of the second thin film transistor.

Step Z126, forming data lines, a source and a drain of the first thin film transistor, a source and a drain of the second thin film transistor; the source and the drain of the first thin film transistor being respectively in contact with the active layer of the first thin film transistor; the source and the drain of the second thin film transistor being respectively in contact with the active layer of the second thin film transistor; the source of the first thin film transistor and the source of the second thin film transistor being respectively connected to corresponding data lines.

Step Z127, forming a passivation layer; the passivation layer covering the gate insulating layer, the data lines, the active layer, the source and the drain of the first thin film transistor, the active layer, the source and the drain of the second thin film transistor.

Step Z128, forming a third via hole and a fourth via hole; the third via hole exposing the drain of the first thin film transistor; the fourth via hole exposing the common electrode and the drain of the second thin film transistor.

Step Z129, forming a pixel electrode and a conductive connection structure on the passivation layer; the pixel electrode being connected to the drain of the first thin film transistor through the third via hole; the conductive connection structure filling the fourth via hole, and being in contact with the common electrode and the drain of the second thin film transistor.

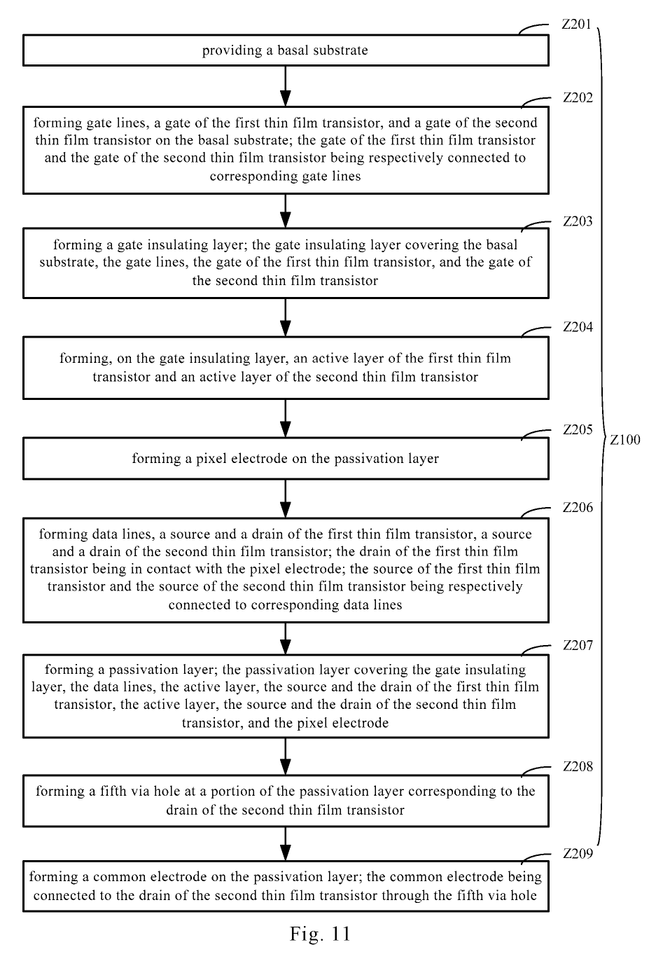

When the pixel structure is applied to an HADS display device, referring to FIG. 11, step Z100 of forming a first thin film transistor, a second thin film transistor, a pixel electrode, and a common electrode; a drain of the first thin film transistor being connected to the pixel electrode, and a drain of the second thin film transistor being connected to the common electrode may include the following steps.

Step Z201, providing a basal substrate.

Step Z202, forming gate lines, a gate of the first thin film transistor, and a gate of the second thin film transistor on the basal substrate; the gate of the first thin film transistor and the gate of the second thin film transistor being respectively connected to corresponding gate lines.

Step Z203, forming a gate insulating layer; the gate insulating layer covering the basal substrate, the gate lines, the gate of the first thin film transistor, and the gate of the second thin film transistor.

Step Z204, forming, on the gate insulating layer, an active layer of the first thin film transistor and an active layer of the second thin film transistor.

Step Z205, forming a pixel electrode on the passivation layer.

Step Z206, forming data lines, a source and a drain of the first thin film transistor, a source and a drain of the second thin film transistor; the drain of the first thin film transistor being in contact with the pixel electrode; the source of the first thin film transistor and the source of the second thin film transistor being respectively connected to corresponding data lines.

Step Z207, forming a passivation layer; the passivation layer covering the gate insulating layer, the data lines, the active layer, the source and the drain of the first thin film transistor, the active layer, the source and the drain of the second thin film transistor, and the pixel electrode.

Step Z208, forming a fifth via hole at a portion of the passivation layer corresponding to the drain of the second thin film transistor.

Step Z209, forming a common electrode on the passivation layer; the common electrode being connected to the drain of the second thin film transistor through the fifth via hole.

In the description of the above embodiments, specific features, structures, materials or characteristics may be combined in any suitable manner in any one or more embodiments or examples.

In the pixel structure, display device and the method for driving the pixel structure provided by the embodiments of the present disclosure, the first thin film transistor of the pixel unit is connected to the pixel electrode of the pixel unit, and the second thin film transistor of the pixel unit is connected to the common electrode of the pixel unit. Therefore, when the first thin film transistor is turned on, the pixel electrode can be charged; when the second thin film transistor is turned on, the common electrode can be charged. When the displaying of the display device is realized, the first thin film transistor and the second thin film transistor may be turned on to charge the pixel electrode and the common electrode, that is, the voltage of the pixel electrode and the voltage of the common electrode can be controlled respectively. In this way, the voltage difference between the pixel electrode and the common electrode in the pixel unit matches the image to be displayed, thereby improving the display quality of the display device. Occurrence of defects such as flicker, greenish image, and residual image can thus be prevented.

The above embodiments are only used for explanations rather than limitations to the present disclosure, the ordinary skilled person in the related technical field, in the case of not departing from the spirit and scope of the present disclosure, may also make various modifications and variations, therefore, all the equivalent solutions also belong to the scope of the present disclosure, the patent protection scope of the present disclosure should be defined by the claims.

1. A pixel structure, comprising:
a plurality of pixel units,
wherein each pixel unit of the plurality of pixel units comprises a first thin film transistor, a pixel electrode, and a common electrode,
wherein a first drain of the first thin film transistor of the pixel unit is connected to the pixel electrode,
wherein each of ones of the plurality of pixel units further comprises a second thin film transistor; and
wherein a second drain of the second thin film transistor is connected to the common electrode.

2. The pixel structure according to claim 1,
wherein the ones of the plurality of pixel units comprise first ones of the plurality of pixel units,
wherein each of second ones of the plurality of pixel units comprises a third thin film transistor, and
wherein a third drain of the third thin film transistor is connected to the common electrode.

3. The pixel structure according to claim 1,
wherein the plurality of pixel units are arranged in an N×M array,
wherein the pixel structure further comprises a plurality of gate lines crossing a plurality of data lines to define a plurality of pixel regions,
wherein each pixel unit of the plurality of pixel units is in a corresponding pixel region,
wherein a quantity of the plurality of gate lines is N+1, and a quantity of the plurality of data lines is M,
wherein for a pixel unit in an i-th row of the plurality of pixel units, a first gate of the first thin film transistor of the pixel unit in the i-th row is connected to an i-th gate line of the plurality of gate lines, and a second gate of the second thin film transistor of the pixel unit is connected to an (i+1)-th gate line, and
wherein 1≤i≤N.

4. The pixel structure according to claim 1,
wherein the plurality of pixel units are arranged in an N×M array,
wherein the pixel structure further comprises a plurality of gate lines crossing a plurality of data lines to define a plurality of pixel regions,
wherein each pixel unit of the plurality of pixel units is in a corresponding pixel region of the plurality of pixel regions,
wherein a quantity of the plurality of gate lines is N+1, and a quantity of the plurality of data lines is M,
wherein for a pixel unit in an i-th row of the plurality of pixel units, a first gate of the second thin film transistor of the pixel unit is connected to an i-th gate line of the plurality of gate lines, and a second gate of the first thin film transistor of the pixel unit is connected to an (i+1)-th gate line, and
wherein 1≤i≤N.

5. The pixel structure according to claim 3,
wherein for a pixel unit in a j-th column of the plurality of pixel units, a first source of the first thin film transistor of the pixel unit in the j-th column is connected to a j-th data line of the plurality of data lines, and a second source of the second thin film transistor of the pixel unit is connected to the j-th data line,
wherein 1≤j≤M.

6. The pixel structure according to claim 4,
wherein for a pixel unit in a j-th column of the plurality of pixel units, a first source of the first thin film transistor of the pixel unit in the j-th column is connected to a j-th data line of the plurality of data lines, and a second source of the second thin film transistor of the pixel unit is connected to the j-th data line,
wherein 1≤j≤M.

7. A display device comprising the pixel structure according to claim 1.

8. A method for driving the pixel structure according to claim 1, comprising:
determining a voltage difference between the pixel electrode and the common electrode of each pixel unit based on an image to be displayed;
turning on the first thin film transistor and the second thin film transistor of the pixel unit based on the voltage difference between the pixel electrode and the common electrode of each pixel unit, and
charging the pixel electrode and the common electrode respectively.

9. The method according to claim 8, wherein the plurality of pixel units are arranged in an N×M array, wherein the pixel structure further comprises a plurality of gate lines crossing a plurality of data lines to define a plurality of pixel regions, wherein each pixel unit of the plurality of pixel units is in a corresponding pixel region, wherein a quantity of the gate lines is N+1, wherein a quantity of the data lines is M,
wherein for a pixel unit in an i-th row of pixel units, a first gate of the first thin film transistor of the pixel unit in the i-th row is connected to an i-th gate line of the plurality of gate lines, and a second gate of the second thin film transistor of the pixel unit is connected to an (i+1)-th gate line, wherein 1≤i≤N,
wherein turning on the first thin film transistor and the second thin film transistor of the pixel unit based on the voltage difference between the pixel electrode and the common electrode of each pixel unit, and charging the pixel electrode and the common electrode respectively comprises:
turning on the first thin film transistor of each pixel unit of the plurality of pixel units in a first row of pixel units through a first gate line of the plurality of gate lines;
charging the pixel electrode of each pixel unit of the plurality of pixel units in the first row of pixel units through a corresponding data line of the plurality of data lines;
based on a voltage difference between the pixel electrode and the common electrode of each pixel unit in the first row of pixel units to an (N−1)-th row of pixel units, and a voltage of the pixel electrode of each pixel unit in an (s−1)-th row of pixel units, determining a voltage of the pixel electrode and a voltage of the common electrode of each pixel unit in an s-th row of pixel units;
turning on the first thin film transistor of each pixel unit in an s-th row of pixel units and the second thin film transistor of each pixel unit in the (s−1)-th row of pixel units through an s-th gate line;
charging the pixel electrode of each pixel unit in the s-th row of pixel units and the common electrode of each pixel unit in the (s−1)-th row of pixel units through a corresponding data line of the plurality of data lines, wherein s is an integer greater than 1 and less than N+1;
based on a voltage difference between the pixel electrode and the common electrode of each pixel unit in the first row of pixel units to an N-th row of pixel units, and a voltage of the pixel electrode of each pixel unit in the N-th row of pixel units, determining a voltage of the common electrode of each pixel unit in an (N+1)-th row of pixel units;
turning on the second thin film transistor of each pixel unit in the N-th row of pixel units through an (N+1)-th gate line of the plurality of gate lines; and
charging the common electrode of each pixel unit in the (N+1)-th row of pixel units through a corresponding data line of the plurality of data lines.

10. The method according to claim 8, wherein the plurality of pixel units are arranged in an N×M array, wherein the pixel structure further comprises a plurality of gate lines crossing a plurality of data lines to define a plurality of pixel regions, wherein each pixel unit of the plurality of pixel units is in a corresponding pixel region of the plurality of pixel regions, wherein a quantity of the plurality of gate lines is N+1, and a quantity of the plurality of data lines is M,
for a pixel unit in an i-th row of the plurality of pixel units, a first gate of the second thin film transistor of the pixel unit is connected to an i-th gate line of the plurality of gate lines, and a second gate of the first thin film transistor of the pixel unit is connected to an (i+1)-th gate line, wherein 1≤i≤N,
wherein turning on the first thin film transistor and the second thin film transistor of the pixel unit based on the voltage difference between the pixel electrode and the common electrode of each pixel unit, and charging the pixel electrode and the common electrode respectively comprises:
turning on the second thin film transistor of each pixel unit of the plurality of pixel units in a first row of pixel units through a first gate line of the plurality of gate lines;
charging the pixel electrode of each pixel unit of the plurality of pixel units in the first row of pixel units through a corresponding data line of the plurality of data lines;
based on a voltage difference between the pixel electrode and the common electrode of each pixel unit in the first row of pixel units to an (N−1)-th row of pixel units, and a voltage of the common electrode of each pixel unit in an (r−1)-th row of pixel units, determining a voltage of the pixel electrode and a voltage of the common electrode of each pixel unit in an r-th row of pixel units;
turning on the second thin film transistor of each pixel unit in an r-th row of pixel units and the first thin film transistor of each pixel unit in the (r−1)-th row of pixel units through an r-th gate line;
charging the common electrode of each pixel unit in the r-th row of pixel units and the pixel electrode of each pixel unit in the (r−1)-th row of pixel units through a corresponding data line of the plurality of data lines, wherein r is an integer greater than 1 and less than N+1;
based on a voltage difference between the pixel electrode and the common electrode of each pixel unit in the first row of pixel units to an N-th row of pixel units, and a voltage of the common electrode of each pixel unit in the N-th row of pixel units, determining a voltage of the pixel electrode of each pixel unit in an (N+1)-th row of pixel units;
turning on the first thin film transistor of each pixel unit in the N-th row of pixel units through an (N+1)-th gate line of the plurality of gate lines; and
charging the pixel electrode of each pixel unit in the (N+1)-th row of pixel units through a corresponding data line of the plurality of data lines.

11. The method according to claim 8,
wherein an absolute value of the voltage difference between the pixel electrode and the common electrode of the pixel unit is in a range of 0V to 4V,
wherein a voltage charged to the pixel electrode through a corresponding first thin film transistor is in a range of 0V to 4V, and
wherein a voltage charged to the common electrode through a corresponding second thin film transistor is in a range of 0V to 4V.

12. A method for manufacturing a pixel structure, comprising:
forming a first thin film transistor, a second thin film transistor, a pixel electrode, and a common electrode,
wherein a first drain of the first thin film transistor is connected to the pixel electrode, and
wherein a second drain of the second thin film transistor is connected to the common electrode.

13. The method according to claim 12, wherein the forming the first thin film transistor, the second thin film transistor, the pixel electrode, and the common electrode comprises:
providing a basal substrate;
forming a common electrode on the basal substrate;
forming gate lines, a first gate of the first thin film transistor, and a second gate of the second thin film transistor on the basal substrate, wherein the first gate of the first thin film transistor and the second gate of the second thin film transistor are respectively connected to corresponding gate lines;
forming a gate insulating layer, wherein the gate insulating layer is on the basal substrate, the gate lines, the first gate of the first thin film transistor, the second gate of the second thin film transistor, and the common electrode;
forming an active layer of the first thin film transistor and an active layer of the second thin film transistor;
forming a first via hole at a portion of the gate insulating layer corresponding to the common electrode;
forming data lines, a source and a drain of the first thin film transistor, a source and a drain of the second thin film transistor wherein the source and the drain of the first thin film transistor are respectively in contact with the active layer of the first thin film transistor, wherein the source and the drain of the second thin film transistor are respectively in contact with the active layer of the second thin film transistor wherein the drain of the second thin film transistor is connected to the common electrode through the first via hole, and wherein the source of the first thin film transistor and the source of the second thin film transistor are respectively connected to corresponding data lines;
forming a passivation layer wherein the passivation layer is on the gate insulating layer, the data lines, the active layer, the source and the drain of the first thin film transistor, the active layer, the source and the drain of the second thin film transistor;
forming a second via hole at a portion of the passivation layer corresponding to the drain of the first thin film transistor; and
forming a pixel electrode on the passivation layer
wherein the pixel electrode is connected to the drain of the first thin film transistor through the second via hole.

14. The method according to claim 12, wherein the forming the first thin film transistor, the second thin film transistor, the pixel electrode, and the common electrode comprises:
providing a basal substrate;
forming a common electrode on the basal substrate;
forming gate lines, a first gate of the first thin film transistor, and a second gate of the second thin film transistor on the basal substrate, wherein the first gate of the first thin film transistor and the second gate of the second thin film transistor are respectively connected to corresponding gate lines;
forming a gate insulating layer, wherein the gate insulating layer is on the basal substrate, the gate lines, the first gate of the first thin film transistor, the second gate of the second thin film transistor, and the common electrode;
forming an active layer of the first thin film transistor and an active layer of the second thin film transistor;
forming data lines, a source and a drain of the first thin film transistor, a source and a drain of the second thin film transistor wherein the source and the drain of the first thin film transistor are respectively in contact with the active layer of the first thin film transistor, wherein the source and the drain of the second thin film transistor are respectively in contact with the active layer of the second thin film transistor wherein the drain of the second thin film transistor is connected to the common electrode through the first via hole, and wherein the source of the first thin film transistor and the source of the second thin film transistor are respectively connected to corresponding data lines;
forming a passivation layer wherein the passivation layer is on the gate insulating layer, the data lines, the active layer, the source and the drain of the first thin film transistor, the active layer, the source and the drain of the second thin film transistor;
forming a third via hole and a fourth via hole wherein the third via hole exposes the drain of the first thin film transistor and the fourth via hole exposes the common electrode and the drain of the second thin film transistor; and
forming a pixel electrode and a conductive connection structure on the passivation layer,
wherein the pixel electrode is connected to the drain of the first thin film transistor through the third via hole, and
wherein the conductive connection structure is in the fourth via hole, and is in contact with the common electrode and the drain of the second thin film transistor.

15. The method according to claim 12, wherein the forming the first thin film transistor, the second thin film transistor, the pixel electrode, and the common electrode comprises:
providing a basal substrate;
forming gate lines, a first gate of the first thin film transistor, and a second gate of the second thin film transistor on the basal substrate, wherein the first gate of the first thin film transistor and the second gate of the second thin film transistor are respectively connected to corresponding gate lines;
forming a gate insulating layer, wherein the gate insulating layer is on the basal substrate, the gate lines, the gate of the first thin film transistor, and the gate of the second thin film transistor;
forming, on the gate insulating layer, an active layer of the first thin film transistor and an active layer of the second thin film transistor;
forming a pixel electrode on the passivation layer;
forming data lines, a source and a drain of the first thin film transistor, a source and a drain of the second thin film transistor wherein the drain of the first thin film transistor is in contact with the pixel electrode wherein the source of the first thin film transistor and the source of the second thin film transistor are respectively connected to corresponding data lines;
forming a passivation layer wherein the passivation layer is on the gate insulating layer, the data lines, the active layer, the source and the drain of the first thin film transistor, the active layer, the source and the drain of the second thin film transistor, and the pixel electrode;
forming a fifth via hole at a portion of the passivation layer corresponding to the drain of the second thin film transistor; and
forming a common electrode on the passivation layer,
wherein the common electrode is connected to the drain of the second thin film transistor through the fifth via hole.

16. The display device according to claim 7,
wherein each pixel unit further comprises a second thin film transistor, and
wherein a drain of the second thin film transistor of the pixel unit is connected to the common electrode of the pixel unit.

17. The display device according to claim 7,
wherein the plurality of pixel units are arranged in an N×M array,
wherein the pixel structure further comprises a plurality of gate lines crossing a plurality of data lines to define a plurality of pixel regions,
wherein each pixel unit of the plurality of pixel units is in a corresponding pixel region,
wherein a quantity of the plurality of gate lines is N+1, and a quantity of the plurality of data lines is M,
wherein for a pixel unit in an i-th row of the plurality of pixel units, a first gate of the first thin film transistor of the pixel unit in the i-th row is connected to an i-th gate line of the plurality of gate lines, and a second gate of the second thin film transistor of the pixel unit is connected to an (i+1)-th gate line, and
wherein 1≤i≤N.

18. The display device according to claim 7,
wherein the plurality of pixel units are arranged in an N×M array,
wherein the pixel structure further comprises a plurality of gate lines crossing a plurality of data lines to define a plurality of pixel regions,
wherein each pixel unit of the plurality of pixel units is in a corresponding pixel region of the plurality of pixel regions,
wherein a quantity of the plurality of gate lines is N+1, and a quantity of the plurality of data lines is M,
wherein for a pixel unit in an i-th row of the plurality of pixel units, a first gate of the second thin film transistor of the pixel unit is connected to an i-th gate line of the plurality of gate lines, and a second gate of the first thin film transistor of the pixel unit is connected to an (i+1)-th gate line, and
wherein 1≤i≤N.

19. The display device according to claim 17,
wherein for a pixel unit in a j-th column of the plurality of pixel units, a first source of the first thin film transistor of the pixel unit in the j-th column is connected to a j-th data line of the plurality of data lines, and a second source of the second thin film transistor of the pixel unit is connected to the j-th data line,
wherein 1≤j≤M.

20. The display device according to claim 18,
wherein for a pixel unit in a j-th column of the plurality of pixel units, a first source of the first thin film transistor of the pixel unit in the j-th column is connected to a j-th data line of the plurality of data lines, and a second source of the second thin film transistor of the pixel unit is connected to the j-th data line,
wherein 1≤j≤M.
